(19) United States
(12) Patent Application Publication
(10) Pub. No.: US 2010/0038519 A1
(43) Pub. Date: Feb. 18, 2010

(54) Image Sensing Module

(76) Inventor: Cho-Yi LIN, Hsinchu (TW)

Correspondence Address: HDLS Patent & Trademark Services, P.O. BOX 220746, CHANTILLY, VA, 20153-0746, US

(21) Appl. No.: 12/189,795

(22) Filed: Aug. 12, 2008

(51) Int. Cl. H01L 27/00

(52) U.S. Cl. 250/208.1

(57) ABSTRACT

An image sensing module includes a carrier and a plurality of image sensing devices, wherein the image sensing devices are electrically connected to the carrier. Each of the image sensing devices has a sensing area, and the sensing areas face different directions. Each of the image sensing devices has a field of view, and there is an overlap between the fields of view of two adjacent image sensing devices. The image sensing module has a wider field of view.

### BACKGROUND

1. Field of the Invention

The present invention relates to a sensing module, and particularly to an image sensing module.

2. Description of Related Art

FIG. 1 is a schematic view of a conventional image sensing module. Referring to FIG. 1, the conventional image sensing module 100 includes a printed circuit board (PCB) 110, an image sensing device 120 and a fish-eye lens 130. The image sensing device 120 is disposed on the PCB 110 and electrically connected to the PCB 110 through wires 140. Moreover, the fish-eye lens 130 is disposed above a sensing area 122 of the image sensing device 120.

In the conventional technique, because the field of view (FOV) of the image sensing device 120 is smaller, the fish-eye lens 130 is used to increase the FOV of the image sensing device 120.

### BRIEF SUMMARY

The present invention relates to an image sensing module for increasing the field of view.

The present invention provides an image sensing module including a carrier and a plurality of image sensing devices, wherein the image sensing devices are electrically connected to the carrier. Each of the image sensing devices has a sensing area, and the sensing areas face different directions. Each of the image sensing devices has a field of view.

In an embodiment of the present invention, the fields of view of two adjacent image sensing devices overlap.

In an embodiment of the present invention, the carrier has a raised portion, the raised portion has a plurality of carrying surfaces facing different directions, and the image sensing devices are respectively disposed on the carrying surfaces.

In an embodiment of the present invention, the carrying surfaces include a first carrying surface and a second carrying surface, and the first carrying surface and the second carrying surface are inclined surfaces. The number of the image sensing devices is two and the image sensing devices are respectively disposed on the first carrying surface and the second carrying surface.

In an embodiment of the present invention, the carrying surface includes a first carrying surface, a second carrying surface and a third carrying surface. The third carrying surface is connected between the first carrying surface and the second carrying surface. The first carrying surface and the second carrying surface are inclined surfaces, and the third carrying surface is a flat surface. The number of the image sensing devices is three, and the image sensing devices are respectively disposed on the first carrying surface, the second carrying surface and the third carrying surface.

In an embodiment of the present invention, the image sensing module further includes a plurality of sub-substrates disposed on the carrier. The sub-substrates respectively have a carrying surface, the carrying surfaces face different directions, and the image sensing devices are respectively disposed on the carrying surfaces.

In an embodiment of the present invention, the sub-substrates include a first sub-substrate and a second sub-substrate, and the carrying surfaces of the first sub-substrate and the second sub-substrate are inclined surfaces. The number of the image sensing devices is two, and the image sensing devices are respectively disposed on the carrying surfaces of the first sub-substrate and the second sub-substrate.

In an embodiment of the present invention, the sub-substrates include a first sub-substrate, a second sub-substrate and a third sub-substrate, wherein the third sub-substrate is disposed between the first sub-substrate and the second sub-substrate. The carrying surfaces of the first sub-substrate and the second sub-substrate are inclined surfaces, and the carrying surface of the third sub-substrate is a flat surface. The number of the image sensing devices is three, and the image sensing devices are respectively disposed on the carrying surfaces of the first sub-substrate, the second sub-substrate and the third sub-substrate.

In an embodiment of the present invention, the sub-substrates are electrically connected to the carrier through wires, solder balls or conductive glues.

In an embodiment of the present invention, the image sensing devices are electrically connected to the sub-substrates through wires, solder balls or conductive glues.

In an embodiment of the present invention, the carrier is a leadframe.

In an embodiment of the present invention, the carrier is a substrate.

In an embodiment of the present invention, the image sensing devices are electrically connected to the carrier through wires, solder balls or conductive glues.

In an embodiment of the present invention, the image sensing module further includes a housing. A portion of the carrier and the image sensing devices are covered by the housing, and the housing has a plurality of openings respectively exposing the sensing areas of the image sensing devices.

In an embodiment of the present invention, the image sensing module further includes a plurality of lenses, wherein the lenses are respectively disposed at the openings.

The image sensing module of the present invention has the plurality of image sensing devices and the sensing areas of the image sensing devices face different directions, so the field of view of the image sensing module can be increased.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic view of a conventional image sensing module.

FIG. 2A is a schematic top-view of an image sensing module according to an embodiment of the present invention.

FIG. 2B is a schematic side-view of the image sensing module of FIG. 2A.

FIGS. 3A to 3C are schematic side-views of three image sensing modules according to another three embodiments of the present invention.

FIG. 4 is a schematic side-view of an image sensing module according to another embodiment of the present invention.

FIG. 5 is a schematic side-view of an image sensing module according to another embodiment of the present invention.

FIG. 6 is a schematic side-view of an image sensing module according to another embodiment of the present invention.

FIG. 7 is a schematic side-view of an image sensing module according to another embodiment of the present invention.

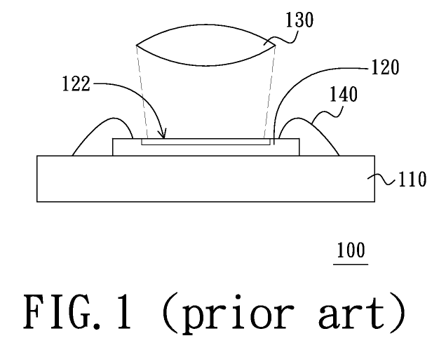

### DETAILED DESCRIPTION

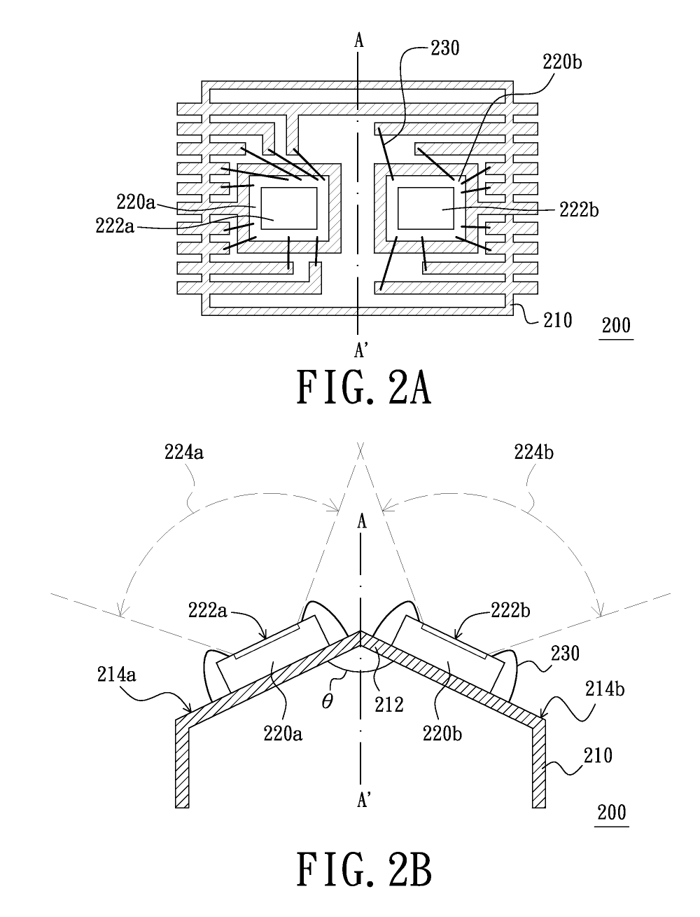

FIG. 2A is a schematic top-view of an image sensing module according to an embodiment of the present invention, FIG. 2B is a schematic side-view of the image sensing module of FIG. 2A, wherein the A-A′ line in FIGS. 2A and 2B passes through the central of the image sensing module. Referring to FIGS. 2A and 2B, the image sensing module 200 of the present embodiment includes a carrier 210 and two image sensing devices 220a and 220b, wherein the image sensing devices 220a and 220b are electrically connected to the carrier 210. The image sensing device 220a has a sensing area 222a and the image sensing device 220b has a sensing area 222b. The sensing areas 222a and 222b face different directions. The image sensing device 220a has a field of view 224a and the image sensing device 220b has a field of view 224b.

In the image sensing module 200, the fields of view 224a and 224b of the two image sensing devices 220a and 220b can overlap. In another embodiment, the fields of view 224a and 224b of the two image sensing devices 220a and 220b does not overlap and the field of view 224a of the image sensing device 220a does not coincide with the field of view 224b of the image sensing device 220b. The carrier 210 is, for example, a leadframe. The image sensing devices 220a and 220b can be complementary metal-oxide-semiconductor (CMOS) image sensing devices or charge coupled devices (CCDs). Moreover, the carrier 210 has a raised portion 212, and the raised portion 212 has a first carrying surface 214a and a second carrying surface 214b. The first carrying surface 214a and the second carrying surface 214b face different directions. The first carrying surface 214a and the second carrying surface 214b are inclined surfaces, and there is a predetermined angle θ between the first carrying surface 214a and the second carrying surface 214b. The image sensing devices 220a and 220b are respectively disposed on the first carrying surface 214a and the second carrying surface 214b. Further, the image sensing module 200 can further include a plurality of wires 230 and the image sensing devices 220a and 220b are electrically connected to the carrier 210 through the wires 230.

The image sensing module 200 of the present embodiment has the two image sensing devices 220a and 220b facing different directions, so the field of view of the image sensing module 200 includes the fields of view 224a and 224b of the two image sensing devices 220a and 220b. Therefore, the field of view of the image sensing module 200 of the present embodiment can be greatly increased.

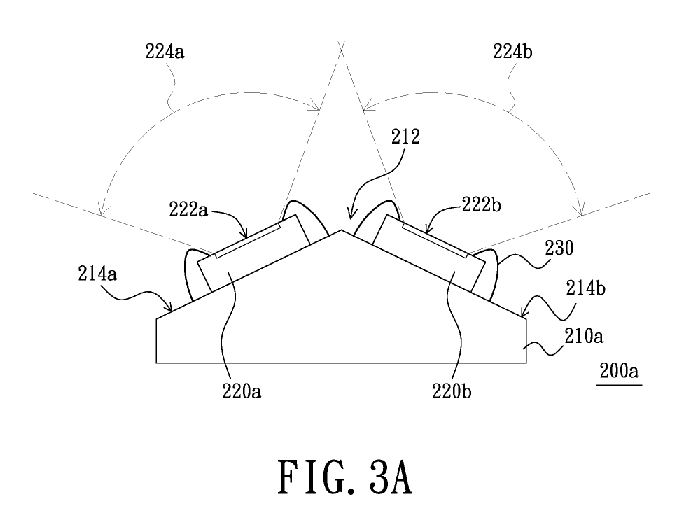

Moreover, although the carrier 210 of the image sensing module 200 of the present embodiment is the leadframe, in another embodiment (referring to the image sensing module 200a of FIG. 3A), the carrier 210a can be a substrate such as PCB. Furthermore, although the image sensing devices 220a and 220b of the image sensing module 200 of the present embodiment are electrically connected to the carrier 210 through the wires 230, in other embodiments, the image sensing device 220a and 220b can be electrically connected to the carrier 210 through solder balls 270 (referring to FIG. 3B), conductive glues 280 (referring to FIG. 3C) or other means.

In the present invention, the number of the image sensing devices 220a and 220b can be greater than two and the number of the carrying surfaces of the raised portion 212 of the carrier 210 should be corresponded to the number of the image sensing devices. Another image sensing module including three image sensing devices according to another embodiment will be described below. However, the number of the image sensing devices of the present invention should not be limited.

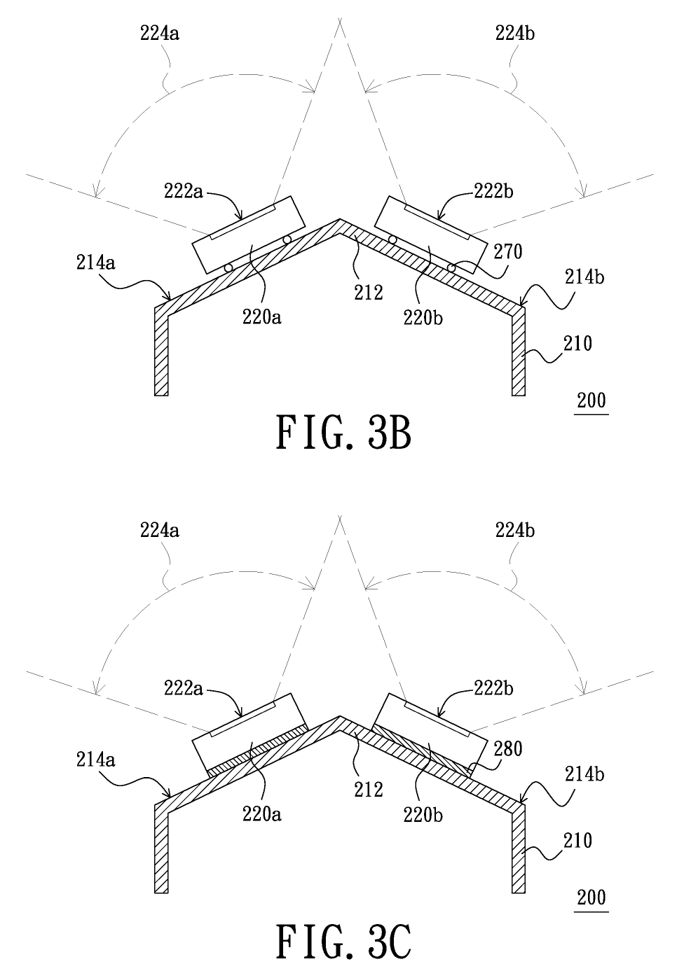

FIG. 4 is a schematic side-view of an image sensing module according to another embodiment of the present invention. Referring to FIG. 4, the image sensing module 200b of the present embodiment includes three image sensing devices 220a, 220b and 220c, and the raised portion 212b of the carrier 210b includes three carrying surfaces (i.e. the first carrying surface 214a, the second carrying surface 214b and the third carrying surface 214c). The third carrying surface 214c is connected between the first carrying surface 214a and the second carrying surface 214b. The first carrying surface 214a and the second carrying surface 214b are inclined surfaces, and the third carrying surface 214c is a flat surface. The image sensing devices 220a, 220b and 220c are respectively disposed on the first carrying surface 214a, the second carrying surface 214b and the third carrying surface 214c. The image sensing devices 220a has a sensing area 222a, the image sensing devices 220b has a sensing area 220b, and the image sensing devices 220c has a sensing area 222c. Further, there is an overlap between the fields of views of two adjacent image sensing devices. In other words, there is an overlap between the fields of view 224a and 224c of the image sensing devices 220a and 220c, and there is an overlap between the fields of view 224b and 224c of the image sensing devices 220b and 220c.

Comparing to the image sensing module 200 of FIG. 2, the number of the image sensing devices of image sensing module 200b of the present embodiment is more than that of the image sensing module 200, so the field of view of the image sensing module 200b is further increased. Moreover, in the present embodiment, the carrier 210b of the image sensing module 200b can be a leadframe or a substrate, and the carrier 210b shown in FIG. 4 is the leadframe. Furthermore, although the image sensing devices 220a, 220b and 220c shown in FIG. 4 is electrically connected to carrier 210b through the wires 230, the image sensing devices 220a, 220b and 220c can also be electrically connected to carrier 210b through the solder balls, the conductive glues or other means.

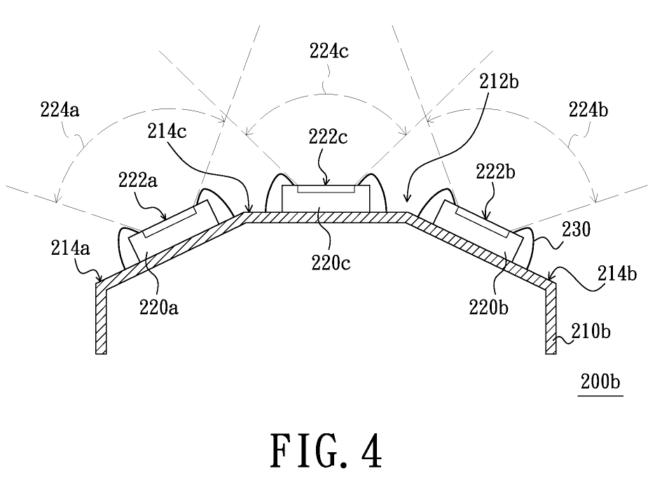

FIG. 5 is a schematic side-view of an image sensing module according to another embodiment of the present invention. Referring to FIG. 5, the image sensing module 200c of the present embodiment is similar to the image sensing module 200 of FIG. 2B, the difference is that the image sensing module 200c further includes a housing 240 and two lenses 250a and 250b. The housing 240 can be an encapsulation and is for covering a portion of the carrier 210 and the image sensing devices 220a and 220b. The housing 240 has two openings 242a and 242b and the openings 242a and 242b respectively expose the sensing areas 222a and 222b of the image sensing devices 220a and 220b. Furthermore, the lenses 250a and 250b are respectively disposed at the openings 242a and 242b of the housing 240 to increase the field of view of each of the image sensing devices 220a and 220b. Thus, the field of view of image sensing module 200c is further promoted.

The housing and the lenses can also be included by the image sensing module having two or more image sensing devices, and the number of the openings of the housing and the number of the lenses should be corresponded to the number of the image sensing devices. The structure of the image sensing module should be realized by one skilled in the art after reading the description, so figures and detailed explanation will be omitted.

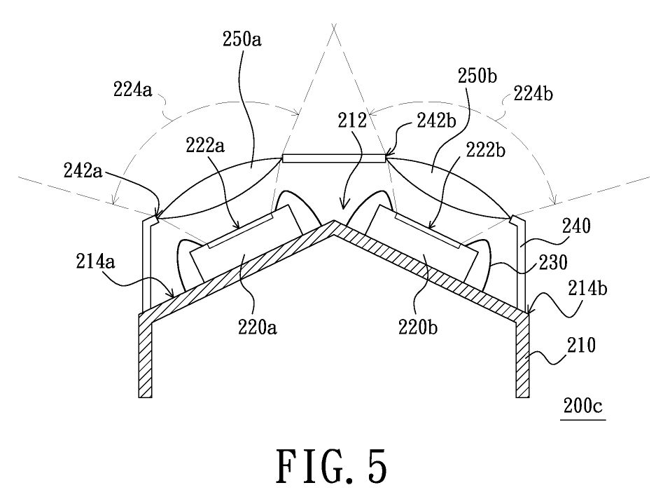

FIG. 6 is a schematic side-view of an image sensing module according to another embodiment of the present invention. Referring to FIG. 6, the image sensing module 200d of the present embodiment is similar to the image sensing module 200 of FIG. 2B, and only the difference will be explained below. Comparing to the image sensing module 200, the carrier 210d of the image sensing module 200d of the present embodiment does not have the raised portion, and the image sensing module 200d further includes a first sub-substrate 260a and a second sub-substrate 260b. The first sub-substrate 260a has a carrying surface 262a, the second sub-substrate 260b has a carrying surface 262b, and the carrying surfaces 262a and 262b are inclined surfaces. Moreover, the image sensing devices 220a and 220b are respectively disposed on the carrying surfaces 262a and 262b of the first sub-substrate 260a and the second sub-substrate 260b. The first sub-substrate 260a and the second sub-substrate 260b are electrically connected to the carrier 210d through the wires 230, and the image sensing devices 220a and 220b are respectively electrically connected to the carrier 210d through the first sub-substrate 260a and the second sub-substrate 260b. Furthermore, in the present embodiment, the carrier 210d of the image sensing module 200d can be a leadframe or a substrate, and the carrier 210d shown in FIG. 6 is leadframe. The first sub-substrate 260a and the second sub-substrate 260b can also be electrically connected to the carrier 210d through the solder balls, the conductive glues or other means.

In the present invention, the number of the sub-substrates should be corresponded to the number of the image sensing devices. Another image sensing module including three image sensing devices and three sub-substrates according to another embodiment will be described below. However, the number of the image sensing devices and the number of the sub-substrates should not be limited.

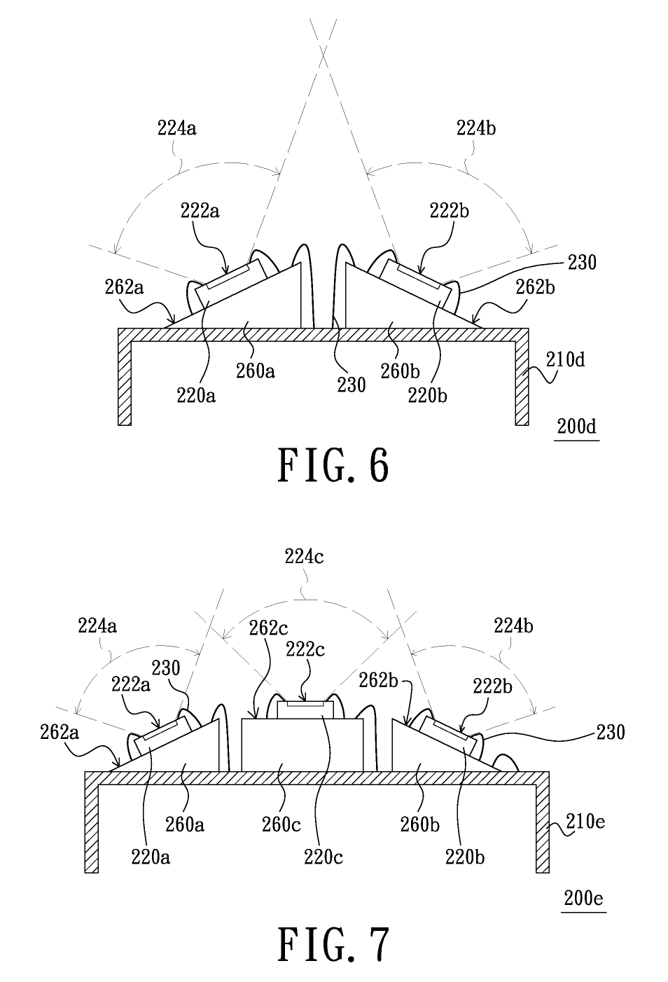

FIG. 7 is a schematic side-view of an image sensing module according to another embodiment of the present invention. Referring to FIG. 7, the image sensing module 200e of the present embodiment includes three image sensing devices 220a, 220b and 220c and three sub-substrates disposed on the carrier 210e. The three sub-substrates include a first sub-substrate 260a, a second sub-substrate 260b and a third sub-substrate 260c. The third sub-substrate 260c is disposed between the first sub-substrate 260a and the second sub-substrate 260b. The first sub-substrate 260a has a carrying surface 262a, the second sub-substrate 260b has a carrying surface 262b, the third sub-substrate 260c has a carrying surface 262c, and the carrying surfaces 262a, 262b and 262c face different directions. The carrying surfaces 262a and 262b of the first sub-substrate 260a and the second sub-substrate 260b are inclined surfaces, and the carrying surface 262c of the third sub-substrate 260c is a flat surface. The image sensing devices 220a, 220b and 220c are respectively disposed on the carrying surfaces 262a, 262b and 262c of the first sub-substrate 260a, the second sub-substrate 260b and the third sub-substrate 260c.

In summary, the image sensing module of the present invention has at least following advantages:
1. The image sensing module of the present invention includes the plurality of the image sensing devices, so the field of view of the image sensing module includes the fields of view of the image sensing devices. Thus, the field of view of the image sensing module of the present invention can be greatly promoted.
2. The image sensing module of the present invention can further includes the lenses disposed above the sensing areas of the image sensing devices to further increase the field of view of the image sensing module of the present invention.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An image sensing module, comprising:
a carrier; and
a plurality of image sensing devices electrically connected to the carrier, wherein each of the image sensing devices has a sensing area, the sensing areas face different directions, each of the image sensing devices has a field of view.

2. The image sensing module as claimed in claim 1, wherein the carrier has a raised portion, the raised portion has a plurality of carrying surfaces facing different directions, and the image sensing devices are respectively disposed on the carrying surfaces.

3. The image sensing module as claimed in claim 2, wherein the carrying surfaces comprises a first carrying surface and a second carrying surface, the first carrying surface and the second carrying surface are inclined surfaces, number of the image sensing devices is two and the image sensing devices are respectively disposed on the first carrying surface and the second carrying surface.

4. The image sensing module as claimed in claim 2, wherein the carrying surface comprises a first carrying surface, a second carrying surface and a third carrying surface, the third carrying surface is connected between the first carrying surface and the second carrying surface, the first carrying surface and the second carrying surface are inclined surfaces, the third carrying surface is a flat surface, number of the image sensing devices is three, the image sensing devices are respectively disposed on the first carrying surface, the second carrying surface and the third carrying surface.

5. The image sensing module as claimed in claim 1, further comprising a plurality of sub-substrates disposed on the carrier, wherein the sub-substrates respectively have a carrying surface, the carrying surfaces face different directions, and the image sensing devices are respectively disposed on the carrying surfaces.

6. The image sensing module as claimed in claim 5, wherein the sub-substrates comprise a first sub-substrate and a second sub-substrate, the carrying surfaces of the first sub-substrate and the second sub-substrate are inclined surfaces, number of the image sensing devices is two, and the image sensing devices are respectively disposed on the carrying surfaces of the first sub-substrate and the second sub-substrate.

7. The image sensing module as claimed in claim 5, wherein the sub-substrates comprise a first sub-substrate, a second sub-substrate and a third sub-substrate, the third sub-substrate is disposed between the first sub-substrate and the second sub-substrate, the carrying surfaces of the first sub-substrate and the second sub-substrate are inclined surfaces, the carrying surface of the third sub-substrate is a flat surface, number of the image sensing devices is three, and the image sensing devices are respectively disposed on the carrying surfaces of the first sub-substrate, the second sub-substrate and the third sub-substrate.

8. The image sensing module as claimed in claim 5, wherein the sub-substrates are electrically connected to the carrier through wires, solder balls or conductive glues.

9. The image sensing module as claimed in claim 5, wherein the image sensing devices are electrically connected to the sub-substrates through wires, solder balls or conductive glues.

10. The image sensing module as claimed in claim 1, wherein the carrier is a leadframe.

11. The image sensing module as claimed in claim 1, wherein the carrier is a substrate.

12. The image sensing module as claimed in claim 1, wherein the image sensing devices are electrically connected to the carrier through wires, solder balls or conductive glues.

13. The image sensing module as claimed in claim 1, further comprising a housing, wherein a portion of the carrier and the image sensing devices are covered by the housing, and the housing has a plurality of openings respectively exposing the sensing areas of the image sensing devices.

14. The image sensing module as claimed in claim 13, further comprising a plurality of lenses, wherein the lenses are respectively disposed at the openings.

15. The image sensing module as claimed in claim 1, wherein the fields of view of two adjacent image sensing devices overlap.
